(19) United States
(12) Patent Application Publication
(10) Pub. No.: US 2013/0058043 A1
(43) Pub. Date: Mar. 7, 2013

(54) HEAT SINK WITH A STACK OF METAL LAYERS HAVING CHANNELS THEREIN

(71) Applicants: Steve Czapla, Landing, NJ (US); Robert Mann, JR., Mt. Arlington, NJ (US); David A. Ramsey, City of Maplewood, NJ (US); Todd R. Salamon, City of New Providence, NJ (US)

(72) Inventors: Steve Czapla, Landing, NJ (US); Robert Mann, JR., Mt. Arlington, NJ (US); David A. Ramsey, City of Maplewood, NJ (US); Todd R. Salamon, City of New Providence, NJ (US)

(73) Assignees: Weiss-Aug Co. Inc, East Hanover, NJ (US); Alcatel-Lucent, USA Inc., Murray Hill, NJ (US)

(21) Appl. No.: 13/454,967

(22) Filed: Apr. 24, 2012

Related U.S. Application Data
(63) Continuation-in-part of application No. 13/199,565, filed on Sep. 3, 2011.

(51) Int. Cl. H05K 7/20; B23P 11/00

(52) U.S. Cl. 361/702; 29/428

(57) ABSTRACT

An apparatus, comprising a heat sink located on a surface of an electronic device, the heat sink including a plurality of metal layers wherein: at least one exterior edge of the metal layers faces the surface, the metal layers form a stack running along the surface, and the metal layers have a plurality of openings in a major surface of the metal layers, the openings configured to carry a fluid there-through.

### CROSS-REFERENCE TO RELATED APPLICATIONS

The present application is a continuation-in-part application to the previously filed U.S. patent application Ser. No. 13/199,565 filed Sep. 3, 2011, titled LAMINATED HEAT SINKS, filed by Todd R. Salamon and David A. Ramsey, which is incorporated herein by reference in its entirety.

### STATEMENT OF GOVERNMENT INTEREST IN THE INVENTION

The present application was made with government support under Department of Energy Grant No. Government (DE-EE0002895). The United States government may have certain rights in the invention.

### TECHNICAL FIELD

The invention relates to heat sinks, methods of making heat sinks, and apparatus including heat sinks.

### BACKGROUND

This section introduces aspects that may help facilitate a better understanding of the inventions. Accordingly, the statements of this section are to be read in this light and are not to be understood as admissions about what is prior art or what is not prior art.

Many active electronic components and active optical components internally generate heat, which is dissipated so that the components can operate at a desired temperature and/or so that the components will continue to operate over a desired lifetime. An inability to adequately dissipate the internally generated heat can limit capacities and/or functionalities of such components and/or can result in the premature failure of such components. Often, the dissipation of heat produced by such active components involves using air as a medium to transport the heat away. For example, a heat sink may be attached to a heat producing component, and a flow of air past the heat sink will provide the cooling that primarily dissipates the heat from the heat sink.

Some heat sinks are constructed with large and/or specialized surfaces that improve the transfer of heat to coolant air. Unfortunately, such heat sinks may have a large physical form factor that can interfere with the circulation of air thereby interfering with the overall dissipation of heat from such an active component and/or from a circuit board holding such an active component.

Some heat sinks have channels that direct the flow of air to improve the transfer of heat to the air. One such heat sink includes an array of parallel fins that both directs the flow of air and adds more surface area for transferring heat from the heat sink to the air. Other such heat sinks include channels that have walls on all lateral sides.

### SUMMARY

One embodiment is an apparatus, comprising a heat sink located on a surface of an electronic device, the heat sink including a plurality of metal layers wherein: at least one exterior edge of the metal layers faces the surface, the metal layers form a stack running along the surface, and the metal layers have a plurality of openings in a major surface of the metal layers, the openings configured to carry a fluid there-through.

In some embodiments, major surfaces of the layers may be configured to be substantially perpendicular to the surface of the electronic device.

In some such embodiments, the major surfaces of the metal layers may be substantially parallel to each other.

In any of the above embodiments, the stack may include at least about ten metal layers.

In some embodiments, openings in the metal layers may be substantially aligned in the stack to form a channel configured to carry the fluid there-through.

In some such embodiments, the openings form an ordered pattern in the metal layers.

In any such embodiments, the openings may have a same pattern in each one of the metal layers.

In any of the above embodiments, odd-numbered ones or sub-stacks of the metal layers of the stack may have a first pattern of the openings, and even numbered ones or sub-stacks of the metal layers of the stack may have a second different second pattern of the openings.

In any of the above embodiments, the plurality of metal layers may be configured such that each of the metal layers are physically connected to form a rigid structure.

In any of the above embodiments, the metal layers may include at least one through-hole in the major surface, the through-holes are aligned to hold a rod therein. The rod is configured to pass through the aligned holes of at least two of the metal layers.

In any of the above embodiments, the metal layer may include a through-hole passing through a top edge of the metal layers and a rod. The top edge is substantially parallel with the surface. The rod is in the through-holes and fixes the one or more metal layers to the surface.

In any of the above embodiments, at least a portion of one the exterior edges of the metal layers, which are configured to not face the surface, may be bonded together.

In any of the above embodiments, at least a portion of the facing major surfaces of adjacent ones of the metal layers may include a bonding material thereon. The bonding material bonds the adjacent metal layers together.

In any of the above embodiments, the facing major surfaces of adjacent ones of the metal layers may include a first boss and a second boss, respectively, wherein the first and second bosses are configured to fit together such that the adjacent metal layers are held together.

In any of the above embodiments, the surface of the electronics device may correspond to the surface of a metal base layer located above heat-generating portions of the electronic device. A bonding material layer may be located on the surface of the metal base layer, wherein the bonding material layer is configured to bond to the at least one exterior edge of the metal layers

Another embodiment is method of manufacturing an apparatus. The method comprises providing a plurality of metal layers, and forming a stack of the metal layers. The stack having a layer-stacking direction configured to run along a surface of an electronic device. The method comprises attaching the heat sink to the devices such that least one exterior edge of the metal layers faces the surface, and the metal layers have a plurality of openings in a major surface of the metal layers, the openings configured to carry a fluid there-through.

In some embodiments, providing the plurality of metal layers includes forming a pattern of the openings in the metal layers.

In some embodiments, forming of the stack of metal layers includes physically connecting neighboring ones of the metal layers to be fixed in contact with each other along major surfaces thereof.

Some embodiments of the method further include physically fixing the stack of the metal layers to the surface.

Some embodiments of the method further include bonding the at least one exterior edge that faces the surface of the electronic device, to the surface of the electronic device.

### BRIEF DESCRIPTION OF THE DRAWINGS

The embodiments of the disclosure are best understood from the following detailed description, when read with the accompanying FIGUREs. Some features in the figures may be described as, for example, “top,” “bottom,” “vertical” or “lateral” for convenience in referring to those features. Such descriptions do not limit the orientation of such features with respect to the natural horizon or gravity. Various features may not be drawn to scale and may be arbitrarily increased or reduced in size for clarity of discussion. Reference is now made to the following descriptions taken in conjunction with the accompanying drawings, in which:

FIG. 1A presents an exploded perspective view of an example apparatus of the present disclosure;

FIG. 1B shows a detailed view of a portion of the apparatus shown in FIG. 1A;

FIG. 2 presents an exploded perspective view of another example apparatus of the present disclosure;

FIG. 3 presents an exploded perspective view of another example apparatus of the present disclosure;

FIG. 4 presents a perspective view of an example apparatus of the present disclosure after the connection of metal layers together to form a stack;

FIG. 5 presents a flow diagram of an example method of manufacturing an apparatus of the disclosure, such as any of the example apparatuses described in the context of FIGS. 1-4; and

FIG. 6 presents a flow diagram of another example method of manufacturing an apparatus of the disclosure, such as any of the example apparatuses described in the context of FIGS. 1-4.

In the Figures and text, similar or like reference symbols indicate elements with similar or the same functions and/or structures.

In the Figures, the relative dimensions of some features may be exaggerated to more clearly illustrate one or more of the structures or features therein.

Herein, various embodiments are described more fully by the Figures and the Detailed Description. Nevertheless, the inventions may be embodied in various forms and are not limited to the embodiments described in the Figures and Detailed Description of Illustrative Embodiments.

### DETAILED DESCRIPTION

The description and drawings merely illustrate the principles of the inventions. It will thus be appreciated that those skilled in the art will be able to devise various arrangements that, although not explicitly described or shown herein, embody the principles of the inventions and are included within its scope. Furthermore, all examples recited herein are principally intended expressly to be for pedagogical purposes to aid the reader in understanding the principles of the inventions and concepts contributed by the inventor(s) to furthering the art, and are to be construed as being without limitation to such specifically recited examples and conditions. Moreover, all statements herein reciting principles, aspects, and embodiments of the inventions, as well as specific examples thereof, are intended to encompass equivalents thereof. Additionally, the term, “or,” as used herein, refers to a non-exclusive or, unless otherwise indicated. Also, the various embodiments described herein are not necessarily mutually exclusive, as some embodiments can be combined with one or more other embodiments to form new embodiments.

U.S. Patent Application Publication No. 2009/0321045 is incorporated herein by reference in its entirety.

The thermal resistance is a physical property of a heat sink positioned to transport heat away from a heat-producing component. The thermal resistance is given by:

R_{heat sink}=(T_{component}−T_{inlet fluid})/Q_{component}.

Here, T_{component} is the component's temperature, T_{inlet fluid} is the temperature of the fluid input to cool the heat sink, and Q_{component} is the heat power produced by the heat-producing component. Thus, for a given heat power, Q_{component}, a smaller thermal resistance, R_{heat sink}, implies that the difference between the temperature, T_{component}, of the heat-producing component and the temperature, T_{inlet fluid}, of the fluid input for cooling the component is smaller. For that reason, a small thermal resistance, R_{heat sink}, may be preferable.

A heat sink may have a small thermal resistance, R_{heat sink}, because the heat sink has a complex three-dimensional (3D) structure. For example, a complex 3D structure may provide a large surface to volume ratio for better transferring heat to a coolant fluid and/or may provide channels that more effectively control the flow of a coolant fluid through the body of the heat sink. Unfortunately, some heat sinks with complex 3D structures can be expensive to manufacture directly via conventional techniques such as metal casting or metal printing. In particular, such heat sinks can be expensive to manufacture as a single solid block. Also, since a heat sink may be subject to thermal stresses during manufacture and/or operation, e.g., some heat sinks with complex 3D structures can warp or undesirably deform during manufacture and/or operation. For these reasons, different methods of manufacture and/or structural design may be useful for heat sinks with complex 3D structures.

Herein, a heat sink is referred to as having a complex 3D structure if the heat sink has an irregular or regular array of channels for controlling the passage of a coolant fluid through the heat sink. In such complex 3D structures, the channels have, at least, some segments that are closed on all sides transverse to a flow direction of the fluid passing through the heat sink. Some embodiments of such heat sinks have a complex array of substantially parallel channels for passing the coolant fluid through the heat sink. The array of channels may provide a high surface area for the exchange of heat between the heat sink and the coolant fluid and/or may improve the mixing of the coolant fluid to enhance the transfer of heat from the heat sink to the coolant fluid.

Herein, a coolant fluid for a heat sink may be a gas, e.g., air or another conventional gas useable for cooling, or may be a liquid, e.g., water or another conventional liquid useable for cooling. The coolant fluid is able to flow through some of the channels of the embodiments of heat sinks with complex 3D structures.

Embodiments of the present disclosure benefit from the realization that heat sinks with complex 3D features can include a stack of metal layers positionable such that the direction of the stack is along a surface of an electronic device from which the heatsink is to dissipate heat. In such a heat sink, neighboring ones of the metal layer have major surfaces, which are in physical contact in the stack, e.g., in direct physical contact or soldered, brazed, or welded together. In certain embodiments, the metal layer's orientation relative to the surface of the electronic device facilitates heat transfer from the device into the metal layers of the heat sink, and, openings formed in the metal layers enable the flow of a coolant fluid through the openings to further enhance heat transfer out of the heatsink. These design features can beneficially reduce manufacturing costs while still maintaining or reducing the thermal resistance of the heat sink, as compared to other designs not having such features. For example, some embodiments of the present disclosure show thermal resistance reductions of up to 19% for the same pumping power relative to certain parallel fin heat sink designs.

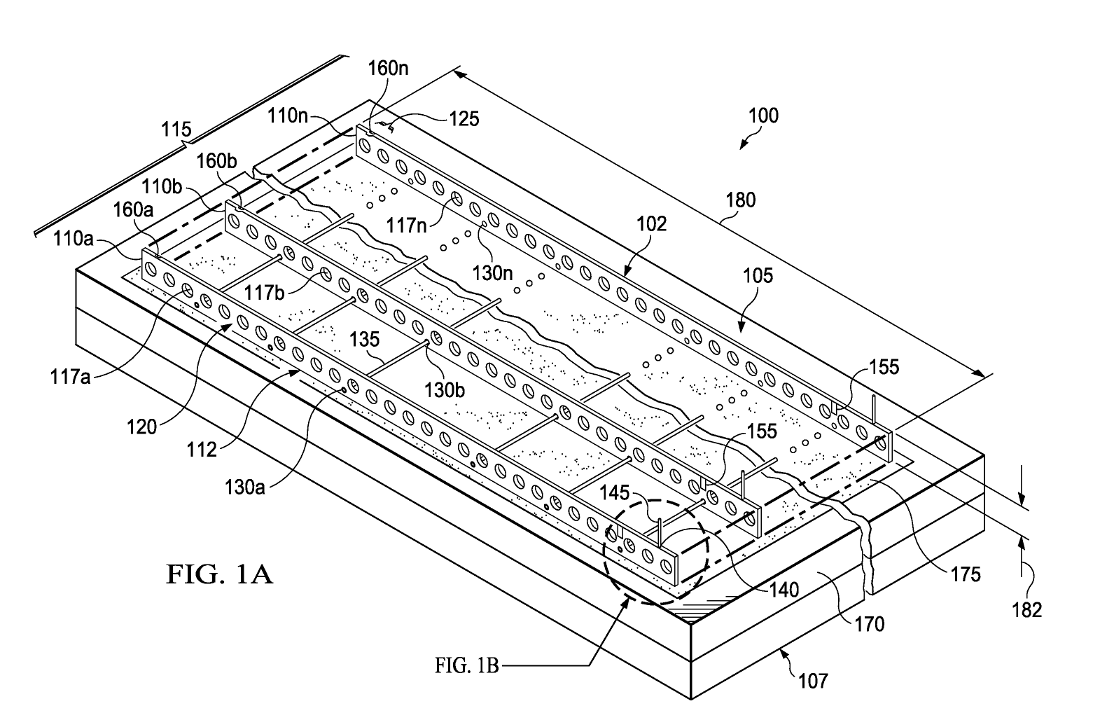

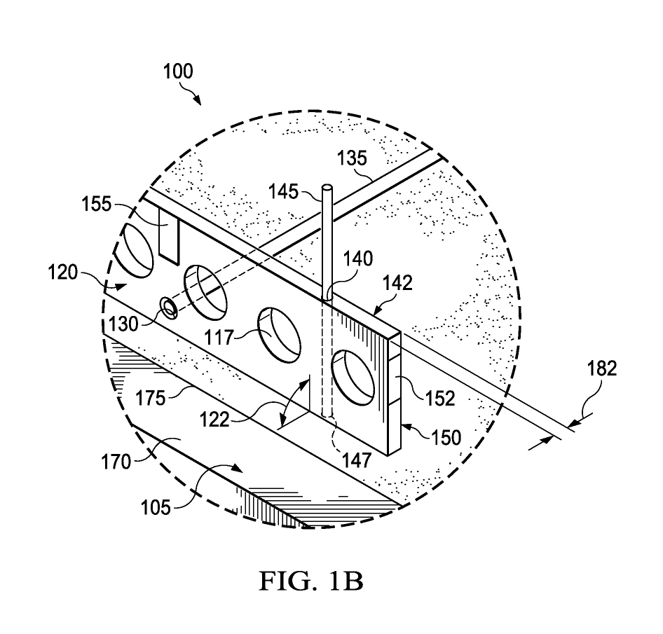

One embodiment of the disclosure is an apparatus. FIG. 1A presents an exploded perspective view of an example apparatus 100 of the present disclosure, and FIG. 1B shows a detailed view of a portion of the apparatus 100 shown in FIG. 1A. The apparatus 100 comprises a heat sink 102 positionable on a surface 105 of an electronic device 107. The heat sink 102 includes a stack of metal layers 110 (e.g., layers 110a, 110b, 110n). At least one exterior edge 112 of the metal layers 110 faces the surface 105. The metal layers 110 form a stack 115 running along the surface 105, and the metal layers 110 have a plurality of openings 117 in a major surface 120 thereof. The openings 117 configured to carry a fluid (e.g., a coolant fluid) there-through.

In some embodiments of the apparatus 100, such as illustrated in FIG. 1A, to facilitate heat transfer from the device 107 to the layers 110, the exterior edges 112 of the metal layers 110 (e.g., of each one of the layers of the stack in some cases) contacts the surface 105. The exterior edges 112 may either directly physically contact the surface 105 or directly physically contact a thermal interface material that directly physically contacts the surface 105. In some embodiments, only some of the exterior edges 112 physically contacts the surface 105. In some embodiments, to facilitate fluid flow through the heat sink 102, each one of the metal layers 110 has the openings 117 there-through.

In some embodiments of the apparatus 100, to facilitate fabrication of the heat sink 102, the major surface 120 of the layers is configured to be substantially perpendicular to the surface, which in some cases can be a planar surface. For instance, as shown in FIG. 1B, the surface 105 and the major surface 120 can form an angle 122 that is a value in the range of about 80 to 100 degrees, and in some case from about 89 to 91 degrees.

As illustrated in FIG. 1A, in some embodiments of the apparatus 100, the major surfaces 120 of each of the metal layers 110 are substantially parallel to each other.

In some embodiments of the apparatus 100, the stack 115 includes at least about ten metal layers 110, and in some cases at least about 100 metal layers 110, and in still other cases, at least about 500 metal layers 110. For example, in different embodiments, the layer 117n shown in FIG. 1A can correspond to a tenth, a one-hundredth, or a five-hundredth layer. Having a large number of metal layers (e.g., least about 100 metal layers 110) can facilitate greater heat transfer over a large area of the surface 105, e.g., for particular applications using electronic devices 107 with high heat generation capabilities.

In some embodiments of the apparatus 100, at least one of the openings (e.g., opening 117a) in one of the metal layers (e.g., layer 110a) is substantially aligned with at least one of the openings (e.g., opening 117b) in an adjacent one of the metal layers (e.g., layer 110b), and, the aligned openings 117a, 117b in the metal layers 110a, 110b form a channel 125 configured to carry the fluid there-through. In some cases, it is desirable for each one of the metal layers 110 to have substantially all of its openings 117 aligned with a corresponding one or more of the openings 117 in an adjacent layer 110.

The term substantially aligned opening, as used herein, means that the area of one opening (e.g., opening 117a) in one layer (e.g., layer 110a) overlaps with at least about 80 percent of the area of another opening (e.g., opening 117b) in the adjacent metal layer (e.g., layer 110b). In some cases, it is desirable for the openings 117a, 117b, . . . 117n forming a channel 125 to be substantially aligned, but not fully aligned. The term fully aligned openings as used herein means that the area of the one opening 117a overlaps with at least about 99 percent of the area of the opening 117b in the adjacent metal layer. Having some misalignment between the substantially aligned openings 117a, 117b in the adjacent layers 110a, 11b, can promote turbulent flow in the fluid configured to pass through the openings 117, which in turn, can increase heat transfer from the metal layer 110a, 110b to the coolant fluid.

As illustrated in FIG. 1A, in some embodiments, the openings 117 in the layers 110 (in some cases each one of the metal layers), form an ordered pattern of the metal layers 110 (e.g., a row of aligned openings 117). Providing the metal layers 110 with the same repeating pattern of openings 117 can advantageously reduce manufacturing costs and simplify the fabrication of the heat sink 102. However, in other embodiments, there is no repeating pattern of openings 117, e.g., the locations of the openings 117 may shift from layer-to-layer.

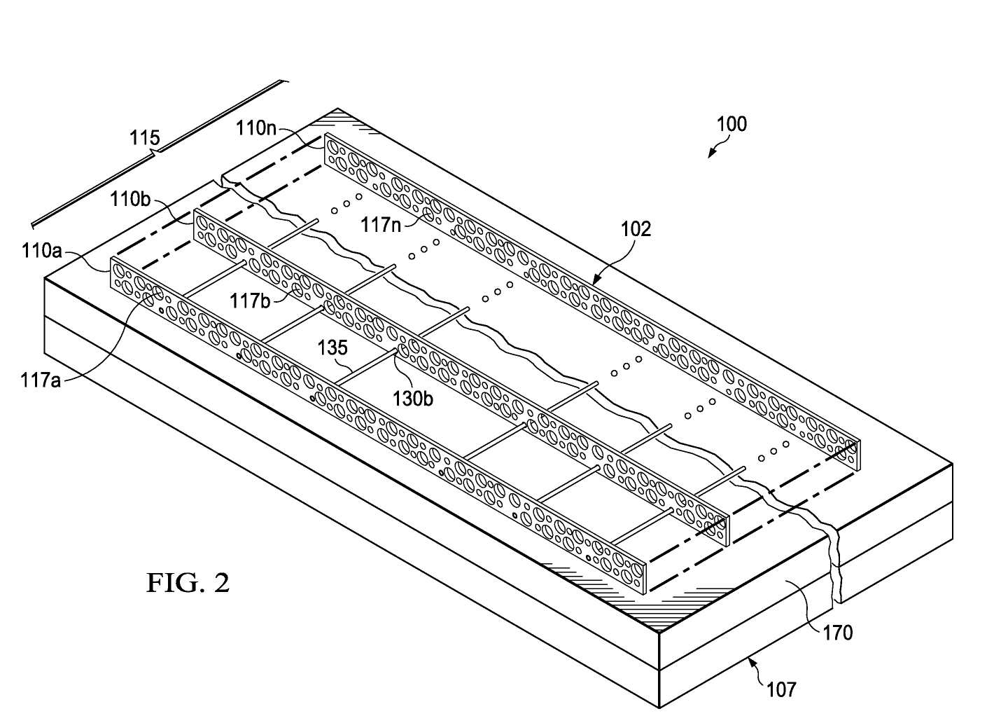

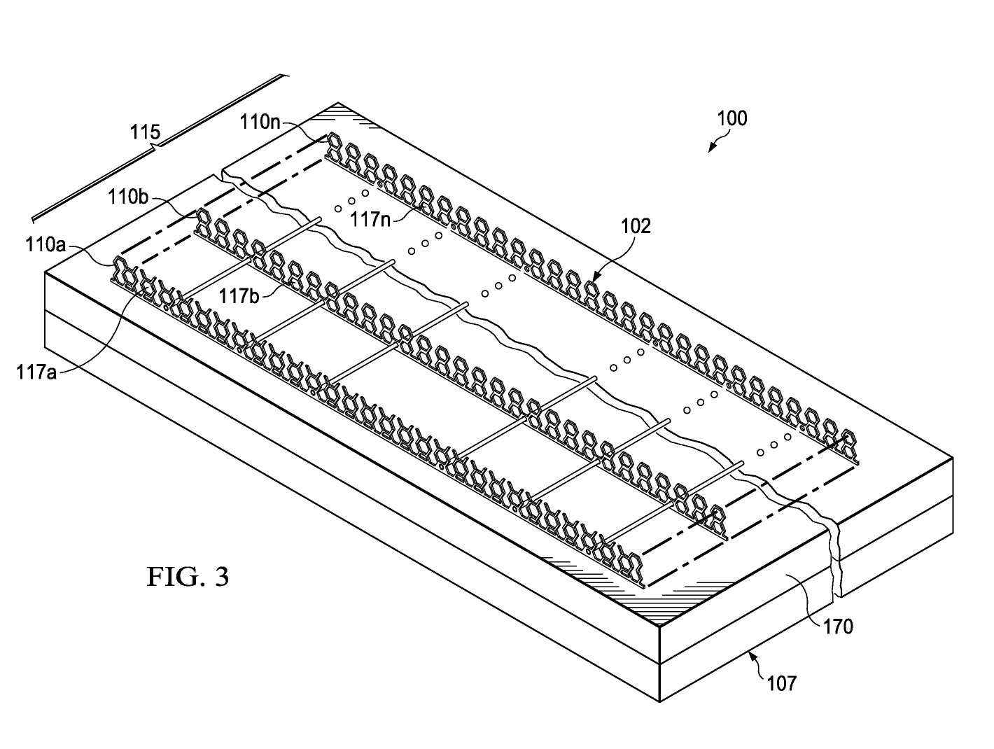

FIGS. 2 and 3 present exploded perspective views of different example embodiments of the apparatus 100.

As illustrated in FIG. 2, there can be a complex pattern of openings 117 in the metal layers 110, and there can be differently sized openings 117 in one, more than one, or all of the metal layers 110.

As illustrated in FIG. 3, the openings 117 can have shapes other than circular shapes. In some cases, hexagonal shaped openings 117 (e.g., equilateral, non-equilateral or distorted shaped hexagons) can be advantageous to promote efficient distribution of the openings 117 throughout the metal layers 110 to thereby maximize the total area of the major surface 120 that includes openings 117. Maximizing the total area of the major surface 120 that includes openings 117, in turn, can facilitate more efficient heat transfer to the coolant fluid by allowing greater flow rates of fluid through the openings 117. In some cases, the use of hexagonal-shaped openings 117 can impart the layers 110 with more mechanical strength to permit manipulation, e.g., during the heat sink's 102 manufacture, without damaging or distorting the individual layers 110.

Additionally, as further illustrated in FIG. 3, different layers 110 can have different patterns of the same-sized and same-shaped openings (e.g., hexagonal-shaped openings). For instance, counting from an outer-most layer (e.g., layer 110a) of the stack 115, odd-numbered ones of the metal layers can have a first pattern of the openings 117a, and even numbered ones of the metal layers (e.g., layer 11ob) can have a second different pattern of the openings 117b. In some cases, providing an alternating pattern of openings in consecutively stacked layers enables the production of turbulence in the coolant fluid passing through the stack of layers thereby improving heat transfer from the heat sink to the fluid. In some embodiments, such as embodiments in which the stack has thin metal layers (e.g., layers with an individual thickness of about 0.25 mm), it can be desirable to assemble a first sub-stack of several metal layers 110 (e.g., from 10 to 20 metal layers in some cases) all having an identical first pattern of openings 117a, and, assemble a second sub-stack of metal layers 110 all having an identical second different pattern of openings 117b. In such embodiments, the odd-numbered ones of the first sub-stack of layers have a first pattern of the openings 117a, and even numbered ones of the second sub-stack of layers have a second different pattern of the openings 117b.

In still other embodiments, to promote fluid turbulence, the metal layers 110, can include openings 117 having various different regular shapes (e.g., squares, triangles, etc . . . ) or irregular shapes, have various different ordered or random arrangements of the openings 117 within each layer 110 and/or different patterns of openings in consecutive layers 110. For instance, in some embodiments, there can be a series of two or more consecutive layers 110 in the stack 115, each layer 110 having a different pattern of openings 117, and, the series of consecutive layers 110 with different patterns of openings 117 there-through can be repeated two or more times in the stack 115.

In some embodiments, the individual layers 110 of the stack 115 can be physically separated from each other, e.g., such that the facing major surfaces 120 of two adjacent layers 110 do not touch each other.

In other embodiments, however, the layers 110 can be connected to each other, e.g., such that the facing major surfaces 120 of two adjacent layers 110 touch each other, e.g., to form a laminated stack 115. Connecting the layers 110 together, e.g., to form a single contiguous piece, can facilitate heat transfer into, and distribution throughout, the heat sink 102, as well as impart the heat sink 102 with mechanically stability, e.g., to facilitate handling during the heat sink's 102 manufacture or placement on the surface 105 of the device 107.

As illustrated in FIG. 1A, in some embodiments, the metal layers 110 (each one of the metal layers in some cases), include at least one through-hole 130 (e.g., holes 130a, 130b, . . . 130n) in major surfaces 120 thereof. The holes 130 (e.g., hole 130a) are positioned along the major surface 120 so as to be aligned with another hole (e.g., hole 130b) in an adjacent one of the metal layers 110 when located in the stack 115. The holes 130 can be configured to hold a rod 135 therein, and the rod 135 can pass through the aligned holes 130a, 130b of at least two of the metal layers 110, 110b. In some cases, the rod 135 is configured to pass through all of the aligned holes 130a, 130b, . . . 130n of the metal layers of the stack 115.

As also illustrated in FIGS. 1A and 1B, in some embodiments, the metal layers 110 (each one of the metal layers in some cases) can include a through-hole 140 passing though a top exterior edge 142 of the metal layer, the top exterior edge 142 being a minor surface that may be, e.g., substantially parallel with the surface 105 of the device 102. In some embodiments, where individual layers are thin (e.g., about 0.25 mm or less) a set of several layers (e.g., 10 or more in some cases) can be bonded together and the hole 140 can be through two or internal layers of the set of layers, to improve the structural integrity of the hole 140. The holes 140 can be configured to hold a rod 145 therein, and the rod 145 can pass through the metal layer 110 to the surface 105, thereby fixing the metal layer 110 to the surface 105. In some cases for example, the rod 145 can be configured to pass through an anchoring hole 147 in the surface 105, and/or the rod 145 can be configured to be bonded to the surface 105.

As further illustrated in FIGS. 1A and 1B, in some cases, at least one the exterior edges (e.g., top edge 142, or side edge 150) of the metal layers 110, e.g., the edges configured to not face the surface 105, are bonded together. For example, portions 152, or in some cases, the entire edge side edge 150 of adjacent metal layers 110 can be bonded together by laser or electrical welding, soldering or brazing or other bonding procedures familiar to those skilled in the art.

As further illustrated in FIGS. 1A and 1B, in some embodiments, at least a portion 155 of the facing major surfaces 120 of adjacent ones of the metal layers (e.g., layers 110a and 110b) include a bonding material physically thereon, the bonding material configured to bond the adjacent metal layers 110a, 110b together. In some cases, the bonding material can include a brazing alloy such as Sn—Ag—Cu and/or Al—Si or other alloys (e.g., 4047 Aluminum, which is sold by JL Anthony and Co. of Providence, R.I. USA) which can be advantageous for bonding metal layers 110 that are composed of aluminum. In other cases the bonding material can include an Ag—In or similar alloys, which can be advantageous for bonding metal layers 110 that are composed of copper. In still other cases, the bonding material can include a solder alloy such a Pb—Sn solder.

As further illustrated in FIG. 1A, in some embodiments, the facing major surfaces 120 of adjacent ones of the metal layers (e.g., layers 110a and 110b), include a first boss 160a and a second boss 160b, respectively, wherein the first and second bosses 160a, 160b are configured to fit together such that the adjacent metal layers 110a, 110b are held together in a fixed relative arrangement in the stack 115. In some cases the bosses 160a, 160b can help to align the layers 110 when forming the stack 115 of layers 110 and/or facilitate locking the layers 110 together.

As further illustrated in FIGS. 1A and 1B, in some embodiments, to facilitate heat transfer to the heat sink 102, the electronic device 107 can further include a metal base layer 170 located above the heat-generating portions of the electronic device 107. In such embodiments, the surface 105 that the exterior edge 112 of the metal layers 110 faces is the surface of the metal base layer 170. In some cases, as illustrated in FIGS. 1A and 1B, the metal base layer 170, can be composed of aluminum or copper, or any thermally conductive material or alloy. In some cases, the base layer 170 can have a same form factor as the heat-generating portions of the electronic device 107 (e.g., the active electronic or optical components). In some cases, the metal base layer 170 can be located directly on the heat-generating portions of the electronic device 107.

In some cases, to facilitate bonding of the metal layers 110 to the base layer 170, or the underlying portions of the electronic device 107, a bonding material layer 175 (e.g., a layer composed of brazing alloy or solder alloy) can be located on the surface 105 of the metal base layer 170. The bonding material layer can be configured to bond to the at least one exterior edge 120 of the metal layers 110. In some cases, for example, the bonding material layer 175 can comprise Sn—Ag—Cu, Ag—In, and/or Pb—Sn alloys, or other alloys familiar to those skilled in the art. The one exterior edge 120 can be contacted to the bonding material layer 175 and then heated to form, e.g., a metal alloy bond connecting the metal layers 110 to the metal base layer 170. In other cases the bonding material layer can include or be an epoxy, thermal glue, cement or similar bonding media.

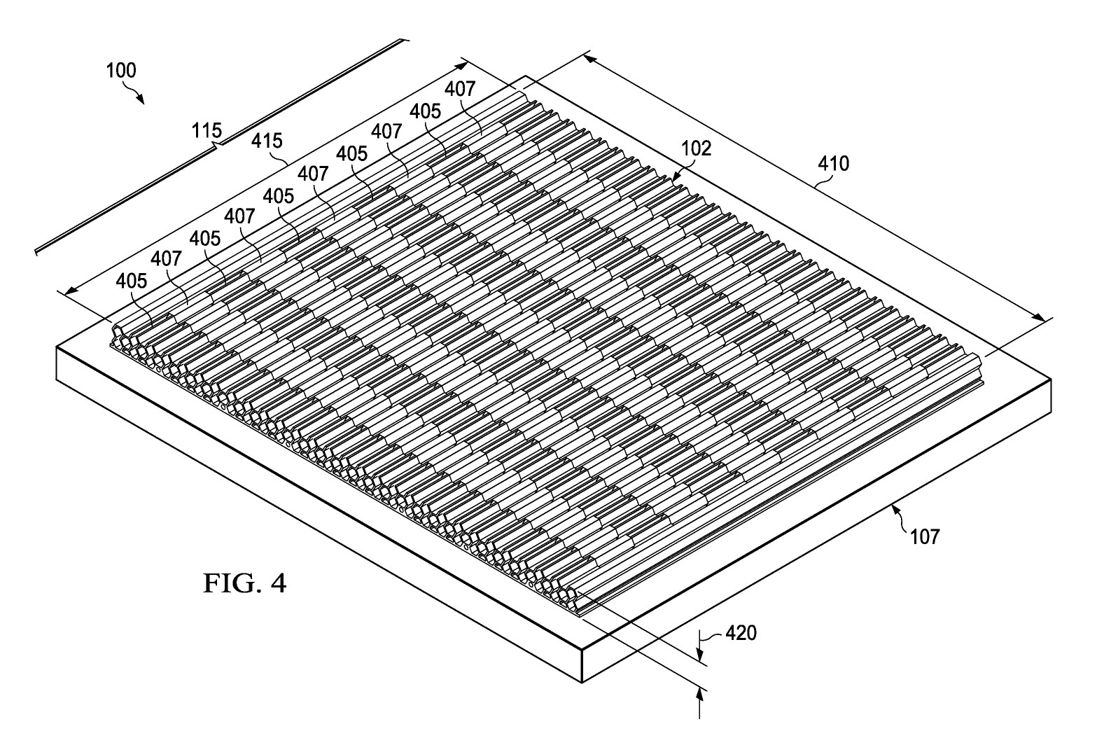

FIG. 4 presents a perspective view of another example apparatus 100 of the present disclosure, after connecting of the metal layers 110 (e.g., FIG. 3) together to form a stack 115, e.g., using any one or more of the above-described connection methods, used alone or in combination. With continuing reference to FIGS. 1A and 1B, for the example apparatus 100 depicted in FIG. 4, the metal layers 110, having two different patterns of openings 117 such as shown in FIG. 3, were connected together as a set of 23 metal layers 110 having a first pattern of openings 117 (e.g., a first sub-stack 405) each set of layers 110 alternating with a set of 24 metal layers 110 (e.g., a second-sub-stack 407) having a second pattern of openings 117, to form the stack 115. Each layer 110 has a length 180 of about 125 mm, a height 182 of about 5.7 mm and thickness 184 of about 0.25 mm. In the example embodiment, six of such sub-stacks 405, 407 are connected in an alternating sequence, to form the stack 115 of the heat sink 102. Some embodiments of the resulting heat sink 102 have dimensions of about 75 mm in width 410, by about 125 mm in length 415, by about 5.7 mm in height 420.

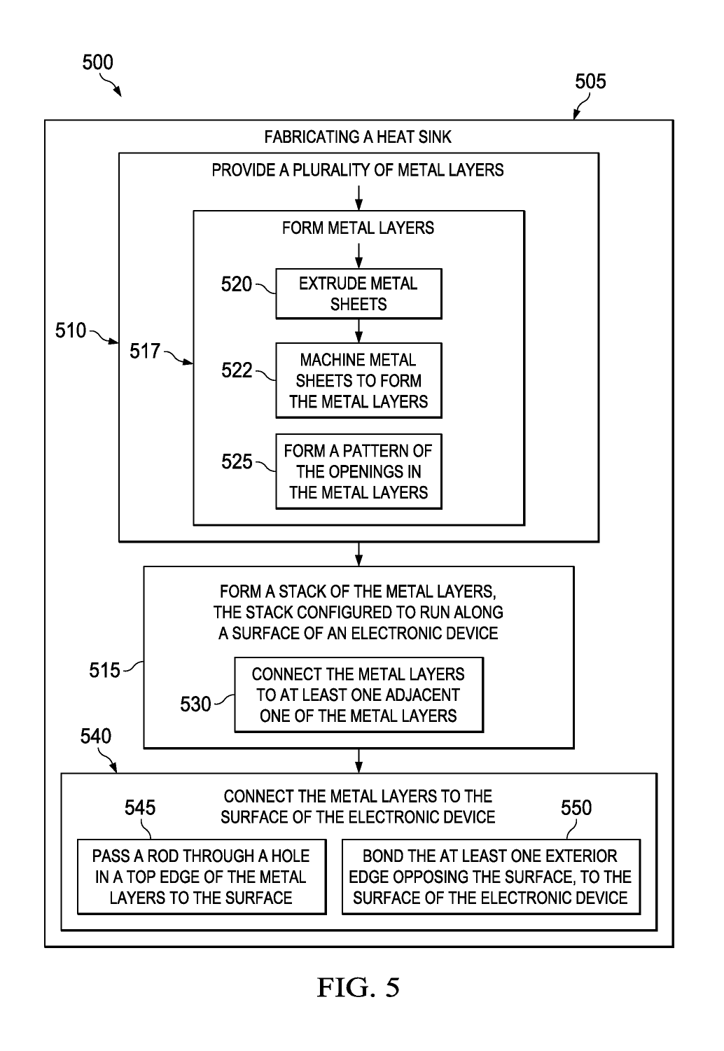

Another embodiment of the disclosure is a method of manufacturing an apparatus. FIG. 5 presents a flow diagram of an example method 500 of manufacturing an apparatus of the disclosure, such as any of the example apparatus 100 described in the context of FIGS. 1-4.

With continuing reference to FIGS. 1A-4, throughout, the example the method 500 comprises a step 505 of fabricating a heat sink 102. Fabricating the heat sink (step 505) includes a step 510 of providing a plurality of metal layers 110 and a step 515 of forming a stack of the metal layers 110. The stack 115 positionable along a heat-transfer surface 105 of an electronic device 107 to be cooled such that the direction of layer-stacking in the stack 115 is along the surface of the electronic device 107. When mounted, a least one exterior edge 112 of the metal layers 110 faces the surface 105, and, the metal layers 117 have a plurality of openings 117 in a major surface 120 of the metal layers 110. The openings 117 are configured to carry a fluid there-through.

In some embodiments the step 510 of providing the metal layers 110 can include a step 517 of forming the metal layer 110, which can include machining, cutting, manufacturing, modifying or manipulating metal. In some example embodiments, the forming step 517 can include a step 520 of extruding metal sheets from an extrusion machine and a step 522 of machining the metal sheets to the dimensions of the layers 110. In some embodiments as part of step 520, for instance, a thin sheet of brazing alloy on top surface of a metal base sheet (e.g., aluminum or copper), and optionally a second thin sheet of brazing alloy on the bottom surface metal base, an be extruded together, e.g., through a roller under high pressure (e.g., about 200 Tons in some case), to produce an extruded metal sheet that includes a two-sheet or three-sheet laminate of the brazing alloy and metal base sheets. In other embodiments, however, a preformed metal sheet composed of a single metal could be used.

In some embodiments, the step 510 of providing the metal layers 110 can include a step 525 of forming a pattern of the openings 117 in the metal layers 110. For example, forming the pattern of openings 117 can include stamping, machine laser or water jet drilling, photo etching or other procedures familiar to one of skill in the art. In some embodiments, the openings are formed in the metal layers 110 such that the openings 117 in one of the metal layers are substantially aligned with corresponding openings 117 in neighboring metal layer(s) 110. In some embodiments, in the stack 115, the aligned openings in the metal layers 110 form a channel 125 configured to carry a fluid there-through in the stack 115. As discussed in the context of FIGS. 1A-3, as part of step 525, the same pattern of openings 117 can be formed in the metal layers 110 or different patterns of openings 117 can be formed in alternating or other consecutive sequences of the metal layers 110.

In some embodiments the step 515 of forming the stack 115 can include a step 530 of connecting the metal layers 110 together to form the stack 115, e.g., by any one or a combination of the connection methods discussed in the context of FIGS. 1A-5. For instance, connecting a metal layer 110 to an adjacent metal layer 110 in step 530 can include bonding at least one the exterior edges 142, 150 of the metal layer 110 (e.g., the edges configured to not face the surface 105) to at least the exterior edge (e.g., the corresponding edge 142, 150) of at least one of adjacent metal layers 110. For instance, connecting a metal layer 110 to an adjacent metal layer 110 in step 530 can include placing a bonding material (e.g., a metal alloy or conductive epoxy in some cases) on at least a portion 155 of at least one of the facing major surfaces 120 of adjacent ones of the metal layers 110 and bonding the adjacent metal layers 110 together through the bonding material, e.g., by raising the temperature above the liquid temperature of the bonding material. For instance, connecting a metal layer 110 to an adjacent metal layer 110 in step 530 can include passing a rod 135 through aligned through-holes 130 in the metal layers 110.

In some embodiments of the method, fabricating the heat sink (step 505) can further include a step 540 of connecting the metal layers 110 to the heat-transfer surface 105 of the electronic device 107 to be cooled. In some cases, connecting the metal layers 110 to the surface 105 (step 540) includes a step 545 of passing a rod 145 through a hole 142 in a top edge 142 of one or more of the metal layers 110, the top edge 142 being substantially parallel with the surface 105. The rod 145 is configured to pass through the metal layer 110 to the surface 105 and thereby fix the metal layer 110 to the surface 105. In some cases, connecting the metal layers 110 to the surface 105 (step 540) includes a step 550 of bonding the at least one exterior edge 112 that faces the surface 105 of the electronic device 107, to the surface 105 of the electronic device 107. In some cases, as part of step 550, the facing exterior edge 112 can positioned on a bonding layer 175 (e.g., a brazing or solder layer) located on a metal base layer 170, and then heated in an oven, to above the liquid temperature of the bonding material (e.g., a metal alloy), to thereby cause the layers 110 to bond to the base layer 170. The metal base layer 170 with the metal layers 110 bonded thereon, can be attached to the device 102 by mechanical (e.g., screws, clamps, bolts) or other bonding processes (e.g., soldering, gluing). In some cases the form factor of the metal base layer 170 can be larger than a perimeter of the stack 115 and the base layer can be attached to the device 102, e.g., by mechanical process via portions of the base layer that are outside the perimeter of the stack 115.

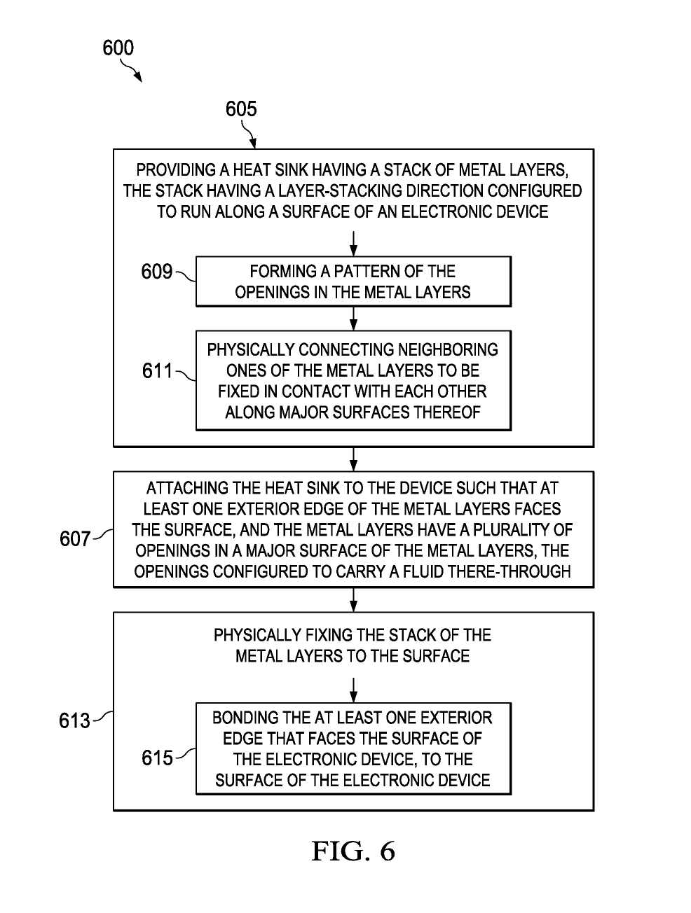

FIG. 6 presents a flow diagram of another example method 600 of manufacturing an apparatus of the disclosure, such as any of the example apparatus 100 described in the context of FIGS. 1-4 as well as the procedures discussed in the context of FIG. 5.

With continuing reference to FIGS. 1A-4, throughout, the example the method 600 comprises a step 605 of providing a heat sink 102 having a stack 115 of metal layers 110, the stack having a layer-stacking direction configured to run along a surface 105 of an electronic device 107. The example method also comprises a step 607 of attaching the heat sink 102 to the device 107 such that least one exterior edge 112 of the metal layers 110 faces the surface 105, and the metal layers 110 have a plurality of openings 117 in a major surface 120 of the metal layers 110, the openings 117 configured to carry a fluid there-through.

In some cases the providing (step 605) includes a step 609 of forming a pattern of the openings 117 in the metal layers 110.

In some cases providing (step 605) the stack 115 of metal layers 110 includes a step 611 of physically connecting neighboring ones of the metal layers 110 to be fixed in contact with each other along major surfaces 120 thereof.

Some embodiments of the method 600 further include a step 613 of physically fixing the stack 115 of the metal layers 110 to the surface. For example, physically fixing the stack 115 of in step 609 can include a step 615 of bonding the at least one exterior edge 112 that faces the surface 105 of the electronic device 107, to the surface 105 of the electronic device 107.

Although the present disclosure has been described in detail, those skilled in the art should understand that they can make various changes, substitutions and alterations herein without departing from the scope of the invention.

What is claimed is:

1. An apparatus, comprising:
a heat sink located on a surface of an electronic device, the heat sink including a plurality of metal layers wherein:
at least one exterior edge of the metal layers faces the surface,
the metal layers form a stack running along the surface, and
the metal layers have a plurality of openings in a major surface of the metal layers, the openings configured to carry a fluid there-through.

2. The apparatus of claim 1, wherein the major surfaces of the layers are substantially perpendicular to the surface of the electronic device.

3. The apparatus of claim 1, wherein the major surfaces of each of the metal layers are substantially parallel to each other.

4. The apparatus of claim 1, wherein the stack includes at least about ten metal layers.

5. The apparatus of claim 1, wherein the openings the metal layers are substantially aligned in the stack, to form a channel configured to carry the fluid there-through.

6. The apparatus of claim 1, wherein the openings form an ordered pattern in the metal layers.

7. The apparatus of claim 1, wherein the openings have a same pattern in each one of the metal layers.

8. The apparatus of claim 1, wherein odd-numbered ones or sub-stacks of the metal layers of the stack have a first pattern of the openings, and even numbered ones or sub-stacks of the metal layers of the stack have a different second pattern of the openings.

9. The apparatus of claim 1, wherein the plurality of metal layers are configured such that each of the metal layers are physically connected form a rigid structure.

10. The apparatus of claim 1, wherein the metal layers include at least one through-hole in the major surface, the through-holes are aligned to hold a rod therein, the rod is configured to pass through the aligned holes of at least two of the metal layers.

11. The apparatus of claim 1, wherein the metal layer includes a through-hole passing through a top edge of the metal layers and a rod, the top edge is substantially parallel with the surface, the rod is in the through-holes and fixes the one or more metal layers to the surface.

12. The apparatus of claim 1, wherein at least a portion of one the exterior edges of the metal layers, which are configured to not face the surface, are bonded together.

13. The apparatus of claim 1, wherein at least a portion of the facing major surfaces of adjacent ones of the metal layers include a bonding material thereon, the bonding material bonds the adjacent metal layers together.

14. The apparatus of claim 1, wherein the facing major surfaces of adjacent ones of the metal layers include a first boss and a second boss, respectively, wherein the first and second bosses are configured to fit together such that the adjacent metal layers are held together.

15. The apparatus of claim 1, wherein the surface of the electronics device corresponds to the surface of a metal base layer located above heat-generating portions of the electronic device, and, a bonding material layer is located on the surface of the metal base layer, wherein the bonding material layer configured to bond to the at least one exterior edge of the metal layers.

16. A method of manufacturing an apparatus, comprising:
providing a heat sink having a stack of metal layers, the stack having a layer-stacking direction configured to run along a surface of an electronic device,
attaching the heat sink to the device such that least one exterior edge of the metal layers faces the surface, and the metal layers have a plurality of openings in a major surface of the metal layers, the openings configured to carry a fluid there-through.

17. The method of claim 16, wherein the providing includes forming a pattern of the openings in the metal layers.

18. The method of claim 16, wherein the stack of metal layers includes physically connecting neighboring ones of the metal layers to be fixed in contact with each other along major surfaces thereof.

19. The method of claim 16, further including physically fixing the stack of the metal layers to the surface.

20. The method of claim 16, further including bonding the at least one exterior edge that faces the surface of the electronic device, to the surface of the electronic device.
